(19) United States
(12) Patent Application Publication
(10) Pub. No.: US 2019/0077013 A1
(43) Pub. Date: Mar. 14, 2019

(54) Robot Diagnosing Method

(71) Applicants: KAWASAKI JUKOGYO KABUSHIKI KAISHA, Kobe-shi (JP); KAWASAKI ROBOTICS (USA), INC., Wixom, MI (US)

(72) Inventors: Tetsuya YOSHIDA, Kobe-shi (JP); Avish Ashok BHARWANI, Santa Clara, CA (US); Hajime NAKAHARA, San Jose, CA (US); Tomokazu ARITA, San Jose, CA (US)

(73) Assignees: KAWASAKI JUKOGYO KABUSHIKI KAISHA, Kobe-shi (JP); KAWASAKI ROBOTICS (USA), INC., Wixom, MI (US)

(21) Appl. No.: 15/699,183

(22) Filed: Sep. 8, 2017

(51) Int. Cl. B25J 9/10; H01L 21/677; B65G 49/07

(52) U.S. Cl. CPC B25J 9/10; H01L 21/67706; B65G 49/07; H01L 21/67742

(57) ABSTRACT

A robot diagnosing method includes: preparing: (1) a line sensor including a light emitter configured to emit a light ray, a light receiver configured to receive the light ray emitted from the light emitter, and a detecting portion configured to detect a position of the detected portion based on a light receiving state of the light receiver, the detected portion being inserted between the light emitter and the light receiver, and (2) a robot including a robot arm and a detected portion configured to move integrally with a wrist portion of the robot arm; detecting the position of the detected portion by the line sensor while linearly moving the wrist portion based on a command value from the robot control portion such that the wrist portion intersects with the light ray; and diagnosing a linearly moving property of the wrist portion based on the position of the detected portion.

### BACKGROUND OF THE INVENTION

### Field of the Invention

The present invention relates to a robot diagnosing method.

### Description of the Related Art

For example, a robot diagnosing method of diagnosing a linearly moving property of a wrist portion of a robot arm by detecting a center position of a work conveyed by the robot arm has been known. Such diagnosing method is performed in a position correcting method used in wafer transfer described in, for example, the specification of Japanese Laid-Open Patent Application Publication No. 2009-49251.

The above publication describes that: a measuring wafer is conveyed to an extended position away from a reference position PO in an x-axis direction by 1 mm; the measuring wafer is transferred to a holding shaft of an aligner; a detecting portion detects an edge of the measuring wafer by rotating once the holding shaft holding the measuring wafer; and a center position P1 is thus measured. Further, the above publication describes that: a movement trajectory is drawn by measurements in an extending direction and contracting direction along the x-axis direction up to Pn; and a processing wafer can be substantially accurately conveyed by setting a movement distance including a correction amount in advance based on the graph.

### SUMMARY OF THE INVENTION

According to the above publication, after the robot arm is stopped once, the center position of the measuring wafer (i.e., a work) is measured. Then, the robot arm and the measuring wafer held by the robot arm are moved, and the same measurement as above is performed again. By repeating such operations, the movement trajectory of the center position of the measuring wafer is drawn, and based on this movement trajectory, the linearly moving property of the wrist portion of the robot arm is diagnosed. The linearly moving property of the wrist portion of the robot arm in an actually moving state (i.e., in a kinetic or dynamic state) is important for robots. However, according to the above publication, such linearly moving property cannot be diagnosed.

An object of the present invention is to provide a robot diagnosing method capable of diagnosing a linearly moving property of a wrist portion of a robot arm in an actually moving state.

To solve the above problems, a robot diagnosing method according to the present invention includes: a first step of preparing a robot and a line sensor, the robot including a robot arm including at least one joint portion, a detected portion configured to move integrally with a wrist portion of the robot arm, and a robot control portion configured to control the robot arm and the wrist portion, the line sensor including a light emitter configured to emit a light ray, a light receiver configured to receive the light ray emitted from the light emitter, and a detecting portion configured to detect a position of the detected portion based on a light receiving state of the light receiver, the detected portion being inserted between the light emitter and the light receiver; a second step of detecting the position of the detected portion by the line sensor while linearly moving the wrist portion based on a command value from the robot control portion such that the wrist portion intersects with the light ray; and a third step of diagnosing a linearly moving property of the wrist portion based on the position of the detected portion detected in the second step.

According to the above configuration, while linearly moving the wrist portion of the robot arm, the position of the detected portion moving integrally with the wrist portion is detected by the line sensor. With this, the linearly moving property of the wrist portion is diagnosed. Thus, the linearly moving property of the wrist portion of the robot arm in the actually moving state can be diagnosed.

The detected portion may include an edge portion linearly extending in a direction along the linear movement of the wrist portion, and the light ray may irradiate the edge portion.

According to the above configuration, the linearly moving property of the wrist portion of the robot arm in the actually moving state can be easily diagnosed.

A part of the wrist portion is formed as the detected portion.

According to the above configuration, the linearly moving property of the wrist portion of the robot arm in the actually moving state can be diagnosed by a simple structure.

An end effector may be attached to the wrist portion, and a part of the end effector may be formed as the detected portion.

According to the above configuration, the linearly moving property of the wrist portion of the robot arm in the actually moving state can be diagnosed without changing the configuration of the robot configured to perform operations.

An exclusive jig including the detected portion may be attached to the wrist portion or to an end effector attached to the wrist portion.

According to the above configuration, the linearly moving property of the wrist portion of the robot arm in the actually moving state can be easily diagnosed without limiting the shape of the end effector.

For example, the light ray emitted from the light emitter may have a band shape.

For example, the light emitter may emit the light ray in an upward/downward direction.

The robot may be a semiconductor manufacturing robot configured to perform an operation in a clean room that is a semiconductor manufacturing site, and in the first step, the robot and the line sensor may be prepared in the clean room.

According to the above configuration, the linearly moving property of the end effector can be diagnosed without taking outside the robot configured to perform operations in the clean room that is the semiconductor manufacturing site. With this, it becomes unnecessary to perform, for example, a cleaning operation of the robot, the cleaning operation being necessary when the robot is taken outside the clean room, the linearly moving property is diagnosed, and the robot is then returned to the clean room. With this, the linearly moving property of the end effector in the actually moving state can be diagnosed in the clean room that is the semiconductor manufacturing site by a procedure that does not require labor or time and is simple.

The line sensor may be included in a prealigner configured to detect a center position of a work subjected to the operation of the robot in the clean room.

According to the above configuration, the linearly moving property of the end effector in the actually moving state can be diagnosed by using the prealigner provided in advance in the clean room that is the semiconductor manufacturing site. With this, for example, an introduction cost and an installation space can be reduced.

For example, the work may be a semiconductor wafer.

### BRIEF DESCRIPTION OF THE DRAWINGS

FIG. 1 is a schematic diagram for explaining a first step of a robot diagnosing method according to an embodiment of the present invention.

FIG. 2 is a side view showing a case where a prealigner prepared in the first step of the robot diagnosing method according to the embodiment of the present invention detects a position of a detected portion.

FIG. 3 is a schematic diagram for explaining second and third steps of the robot diagnosing method according to the embodiment of the present invention.

FIGS. 4A to 4C are schematic diagrams for explaining modified examples of the detected portion detected by the robot diagnosing method according to the embodiment of the present invention.

### DETAILED DESCRIPTION OF THE PREFERRED EMBODIMENTS

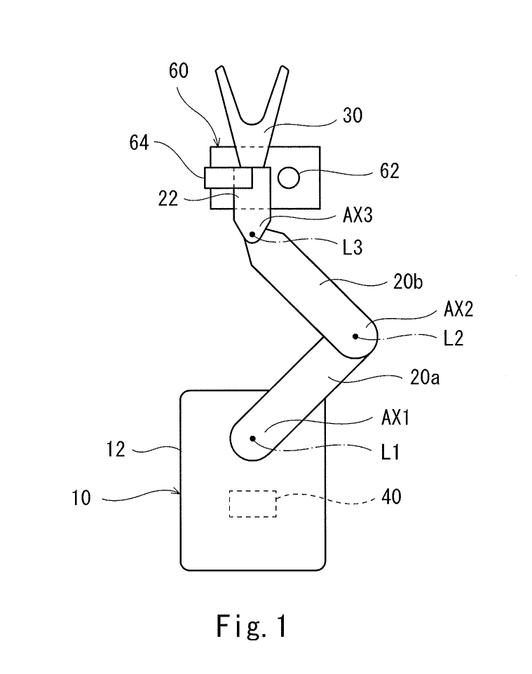

Hereinafter, an embodiment of the present invention will be explained in reference to the attached drawings. In the following explanations and drawings, the same reference signs are used for the same or corresponding components, and a repetition of the same explanation is avoided. A robot diagnosing method according to the embodiment of the present invention will be explained based on FIGS. 1 to 3.

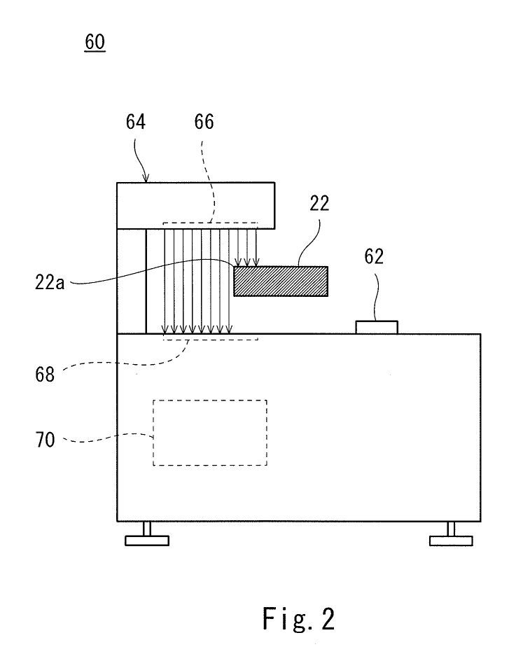

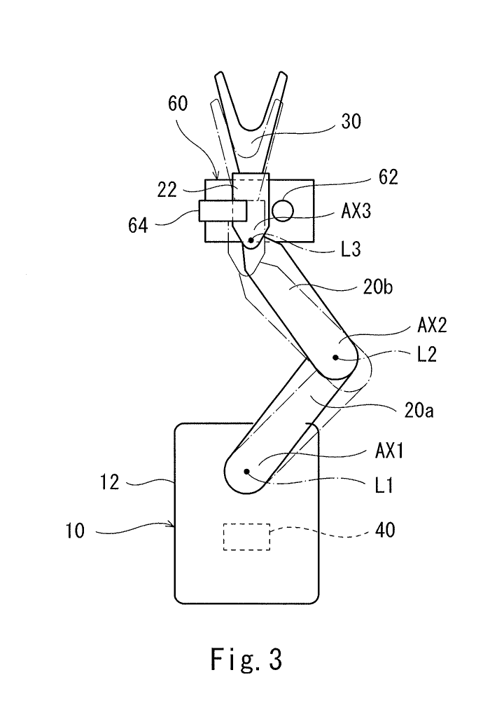

FIG. 1 is a schematic diagram for explaining a first step of the robot diagnosing method according to the embodiment of the present invention. FIG. 2 is a side view showing a case where a prealigner prepared in the first step of the robot diagnosing method according to the embodiment of the present invention detects a position of a detected portion. FIG. 3 is a schematic diagram for explaining second and third steps of the robot diagnosing method according to the embodiment of the present invention.

In a semiconductor manufacturing robot 10 (hereinafter simply referred to as “robot 10”) configured to perform operations in a clean room that is a semiconductor manufacturing site, the robot diagnosing method according to the embodiment of the present invention diagnoses a linearly moving property of a wrist portion 22 of a robot arm 20 in an actually moving state.

It should be noted that “a linearly moving property of a wrist portion 22 of a robot arm 20” denotes a degree of nonoccurrence of a deviation amount of a linear movement (movement in a paper surface upward/downward direction in FIG. 1) of the wrist portion 22 from an ideal linear movement, the linear movement of the wrist portion 22 being based on a command value from a below-described robot control portion 40. To be specific, when the deviation amount of the movement of the wrist portion 22 from the ideal linear movement is relatively small, the linearly moving property is regarded as excellent. In contrast, when the deviation amount of the movement of the wrist portion 22 from the ideal linear movement is relatively large (i.e., when the wrist portion 22 moves while greatly waving), the linearly moving property is regarded as poor.

First Step

First, as shown in FIG. 1, performed is the first step of preparing the robot 10 and a line sensor 64 in the clean room that is the semiconductor manufacturing site. In the present embodiment, the line sensor 64 is included in a prealigner 60 configured to detect a center position of a semiconductor wafer (not shown) as a work.

The robot 10 includes: the robot arm 20 including at least one joint portion AX; an end effector 30 attached to the robot arm 20; and the robot control portion 40 configured to control the robot arm 20 and the end effector 30. The robot 10 according to the present embodiment is a so-called horizontal articulated three-axis robot and includes three joint portions (a first joint portion AX1, a second joint portion AX2, and a third joint portion AX3). The robot 10 further includes a base 12 and a lifting shaft (not shown) provided on an upper surface of the base 12 and extendable in an upward/downward direction. The lifting shaft is configured to be extendable by, for example, an air cylinder (not shown). The robot arm 20 is attached to an upper end portion of the lifting shaft.

The robot arm 20 includes a first arm 20a, a second arm 20b, and the wrist portion 22, each of which is constituted by an elongated member extending in a horizontal direction.

The first arm 20a includes one longitudinal end portion attached to the lifting shaft so as to be rotatable around a vertical axis L1. With this, the first joint portion AX1 is configured. The first arm 20a is configured to be rotatable by an electric motor (not shown). The second arm 20b is attached to the other longitudinal end portion of the first arm 20a. The second arm 20b includes one longitudinal end portion attached to the first arm 20a so as to be rotatable around a vertical axis L2. With this, the second joint portion AX2 is configured. The second arm 20b is configured to be rotatable by an electric motor (not shown).

The wrist portion 22 is attached to the other longitudinal end portion of the second arm 20b so as to be rotatable around a vertical axis L3. With this, the third joint portion AX3 is configured. The wrist portion 22 is configured to be rotatable by an electric motor (not shown).

A tip end of the end effector 30 is divided into two parts and is configured to have a Y shape in a plan view. A base end portion of the end effector 30 is fixed to a tip end of the wrist portion 22 of the robot arm 20.

In the present embodiment, an edge portion 22a of the wrist portion 22 of the robot arm 20 (i.e., a part of the wrist portion of the robot arm) is formed as the detected portion. The edge portion 22a linearly extends in a direction along the linear movement of the wrist portion 22.

Upward and downward movements of the lifting shaft and rotations of the first arm 20a, the second arm 20b, and the wrist portion 22 are controlled by the robot control portion 40.

A specific configuration of the robot control portion 40 is not especially limited and may be realized such that, for example, a publicly known processor (CPU or the like) operates in accordance with a program stored in a storage portion (memory).

As shown in FIG. 2, the prealigner 60 includes: a turn table 62 on which the semiconductor wafer (not shown) as the work is placed; a driving portion (not shown) configured to rotate the turn table 62; and the line sensor 64 configured to detect an outer edge portion of the semiconductor wafer, which is being rotated by the driving portion, to detect a center position of the semiconductor wafer. In the robot diagnosing method according to the present embodiment, the line sensor 64 typically used as above detects the position of the edge portion 22a of the wrist portion 22 of the robot arm 20.

The line sensor 64 includes: a light emitter 66 configured to emit a light ray; a light receiver 68 configured to receive the light ray emitted from the light emitter 66; and a detecting portion 70 configured to detect the detected portion (for example, the outer edge portion of the semiconductor wafer that is rotating, the edge portion 22a of the wrist portion 22 of the robot arm 20, or the like) based on a light receiving state of the light receiver 68, the detected portion being inserted between the light emitter 66 and the light receiver 68. A specific configuration of the detecting portion 70 is not especially limited and may be realized such that, for example, a publicly known processor (CPU or the like) operates in accordance with a program stored in a storage portion (memory).

As shown by a plurality of down arrows in FIG. 2, the light emitter 66 according to the present embodiment emits the light ray in the upward/downward direction. Specifically, the light emitter 66 according to the present embodiment emits the light ray in a downward direction in FIG. 2 (in FIGS. 1 and 3, in a direction from a front paper surface to a rear paper surface). The light receiver 68 arranged under the light emitter 66 as shown in FIG. 2 (in FIGS. 1 and 3, the light receiver 68 is arranged at a rear paper surface side of the light emitter 66) receives the light ray.

The light ray emitted from the light emitter 66 according to the present embodiment has a band shape. Specifically, the light ray according to the present embodiment has the band shape spreading in (i) a width direction along a leftward/rightward direction in FIG. 2, (ii) a height direction along the upward/downward direction in FIG. 2 and perpendicular to the width direction, and (iii) a thickness direction along a direction connecting the front and rear paper surfaces of FIG. 2 and perpendicular to both the width direction and the height direction. It should be noted that the width direction of the light ray coincides with a radial direction of the semiconductor wafer placed on the turn table 62.

Second Step

Next, performed is the second step of detecting the position of the edge portion 22a, which is a part of the wrist portion 22, by the line sensor 64 while linearly moving the wrist portion 22 based on the command value from the robot control portion 40 such that the wrist portion 22 intersects with the light ray. This state is shown in FIG. 3. It should be noted that this position detection may be performed in such a manner that, for example, while the wrist portion 22 is being linearly moved, the line sensor 64 continuously detects the detected portion.

Third Step

Finally, performed is the third step of diagnosing the linearly moving property of the wrist portion 22 in the actually moving state based on the position of the edge portion 22a detected in the second step. It should be noted that the third step may be performed by: seeing the position of the edge portion 22a detected in the second step with human eyes; a program stored in the storage portion based on, for example, a predetermined deviation amount threshold; or the other method.

Effects

In the robot diagnosing method according to the present embodiment, the edge portion 22a of the wrist portion 22 of the robot arm 20 is formed as the detected portion. The line sensor 64 detects the position of the detected portion, and the linearly moving property of the wrist portion 22 of the robot arm 20 is diagnosed based on the detected position. According to conventional procedures, the linearly moving property of the wrist portion of the robot arm is diagnosed by: performing the position detection after the robot arm is stopped once; and repeating such operations. However, such conventional procedures cannot diagnose the linearly moving property of the wrist portion in the actually moving state (i.e., in a kinetic or dynamic state). The robot diagnosing method according to the present embodiment can diagnose the linearly moving property of the wrist portion 22 in the actually moving state by performing the procedure explained in the above embodiment. It should be noted that the linearly moving property of the wrist portion 22 typically deteriorates in proportion to an operating time of the robot 10. To be specific, the linearly moving property deteriorates as the robot 10 deteriorates. Therefore, for example, the life of the robot 10 can be predicted by periodically performing the robot diagnosing method according to the present embodiment to diagnose the linearly moving property. The robot diagnosing method according to the present embodiment can be performed by the procedure that requires less labor and time and is simpler than the conventional methods. Further, since the robot diagnosing method according to the present embodiment performs diagnosis based on the actual movement of the wrist portion 22 of the robot arm 20, it can diagnose the linearly moving property of the wrist portion 22 more accurately than the conventional methods.

Further, in the present embodiment, the wrist portion 22 of the robot arm 20 as the detected portion includes the edge portion 22a extending linearly in the direction along the linear movement, and the light ray irradiates the edge portion 22a. With this, the linearly moving property of the wrist portion 22 of the robot arm 20 in the actually moving state can be diagnosed easily and smoothly.

Further, in the present embodiment, a part of the wrist portion 22 of the robot arm 20 is formed as the detected portion. With this, the linearly moving property of the wrist portion 22 of the robot arm in the actually moving state can be diagnosed by a simple structure.

Further, in the present embodiment, the robot 10 is the semiconductor manufacturing robot configured to perform operations in the clean room that is the semiconductor manufacturing site, and the robot 10 and the line sensor 64 are prepared in the clean room in the first step. Therefore, the linearly moving property of the wrist portion 22 of the robot arm 20 in the actually moving state can be diagnosed without taking outside the robot 10 configured to perform operations in the clean room that is the semiconductor manufacturing site. With this, it becomes unnecessary to perform, for example, a cleaning operation of the robot 10, the cleaning operation being necessary when the robot 10 is taken outside the clean room, the deviation amount is detected, and the robot 10 is then returned to the clean room. As a result, the linearly moving property of the wrist portion 22 of the robot arm 20 in the actually moving state can be diagnosed in the clean room that is the semiconductor manufacturing site by the procedure that does not require labor or time and is simple.

Further, in the present embodiment, the line sensor 64 is included in the prealigner 60 configured to detect the center position of the work (such as the semiconductor wafer) subjected to the operation of the robot 10 in the clean room. With this, the linearly moving property of the wrist portion 22 of the robot arm 20 in the actually moving state can be diagnosed by using the prealigner 60 provided in advance in the clean room that is the semiconductor manufacturing site. As a result, for example, an introduction cost and an installation space can be reduced.

### MODIFIED EXAMPLES

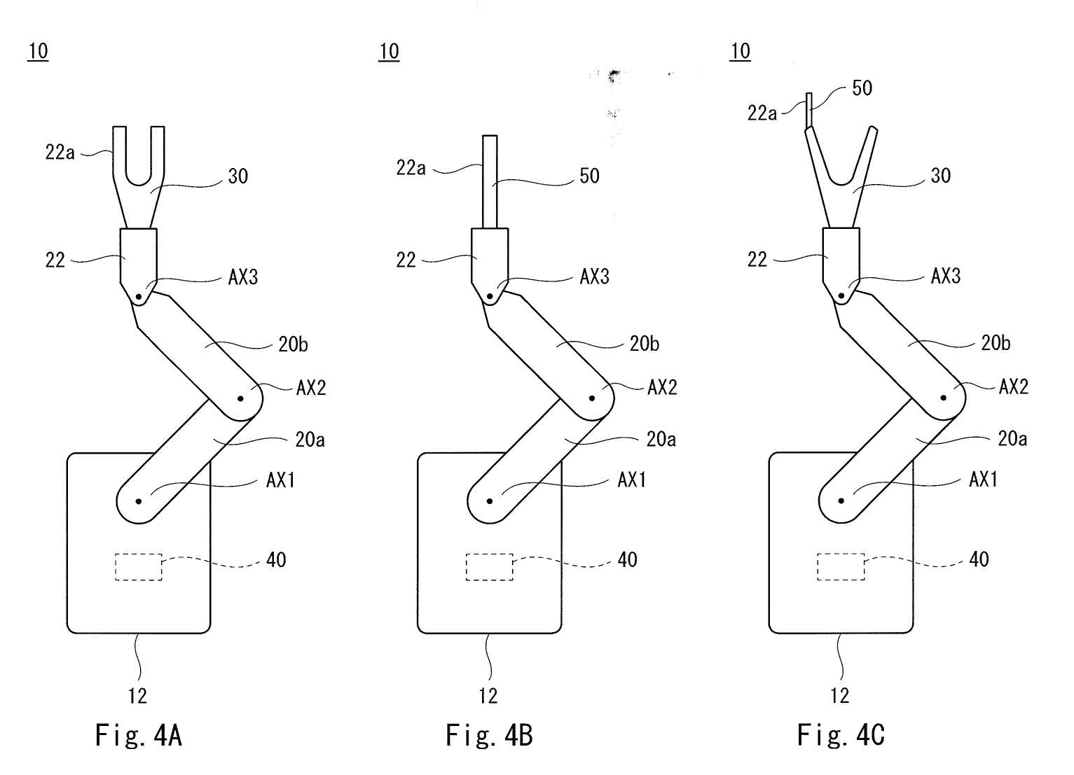

The above embodiment has explained a case where a part of the wrist portion 22 of the robot arm 20 is formed as the detected portion. However, the above embodiment is not limited to this. For example, there are modified examples shown in FIGS. 4A to 4C. FIGS. 4A to 4C are schematic diagrams for explaining the modified examples of the detected portion detected by the robot diagnosing method according to the embodiment of the present invention.

As shown in FIG. 4A, a part of the end effector 30 attached to the wrist portion 22 of the robot arm 20 may be formed as the detected portion. With this, the linearly moving property of the wrist portion 22 of the robot arm 20 in the actually moving state can be diagnosed without changing the configuration of the robot 10 configured to perform operations. In such a case, as shown in FIG. 4A, it is preferable that a part of the end effector 30 include the edge portion 22a linearly extending in the direction along the linear movement of the wrist portion 22.

Or, an exclusive jig 50 including the detected portion may be attached to the wrist portion 22 as shown in FIG. 4B or to the end effector 30 attached to the wrist portion 22 as shown in FIG. 4C. With this, the linearly moving property of the wrist portion 22 of the robot arm 20 in the actually moving state can be easily diagnosed without limiting the shape of the end effector 30. Also in such a case, as shown in FIGS. 4B and 4C, it is preferable that a part of the exclusive jig 50 include the edge portion 22a linearly extending in the direction along the linear movement of the wrist portion 22.

The above embodiment has explained a case where the robot 10 and the line sensor 64 are prepared in the clean room that is the semiconductor manufacturing site. However, the above embodiment is not limited to this. To be specific, the robot 10 and the line sensor 64 may be prepared at a different place. In such a case, the work may be a work other than the semiconductor wafer W.

The above embodiment has explained a case where the line sensor 64 is included in the prealigner 60 configured to detect the center position of the semiconductor wafer. However, the above embodiment is not limited to this. To be specific, the line sensor 64 may be configured as a single device not including the turn table 62, the driving portion configured to rotate the semiconductor wafer, or the like.

The above embodiment has explained a case where the light ray emitted from the light emitter 66 has the band shape. However, the above embodiment is not limited to this. For example, the light ray emitted from the light emitter 66 may be constituted by at least two linear light rays emitted so as to extend in the upward/downward direction with a predetermined interval between the two light rays.

The above embodiment has explained a case where the light emitter 66 emits the light ray in the upward/downward direction (to be specific, a substantially vertical direction). However, the light ray may be emitted in a different direction as long as the light ray can be shielded by the detected portion.

In the above embodiment, the linearly moving property of the wrist portion 22 of the actually moving robot arm 20 including three joint portions is diagnosed. However, the linearly moving property of the wrist portion of the actually moving robot arm including one, two, or four or more joint portions (to be specific, at least one joint portion) can also be diagnosed.

From the foregoing explanation, many modifications and other embodiments of the present invention are obvious to one skilled in the art. Therefore, the foregoing explanation should be interpreted only as an example and is provided for the purpose of teaching the best mode for carrying out the present invention to one skilled in the art. The structures and/or functional details may be substantially modified within the scope of the present invention.

1. A robot diagnosing method comprising:
preparing a robot and a line sensor,
the robot including
a robot arm including at least one joint portion,
a detected portion that is part of a wrist portion of the robot arm, and
a robot control portion configured to control the robot arm and the wrist portion,
the line sensor including
a light emitter configured to emit a band-shaped light ray,
a light receiver configured to receive the band-shaped light ray emitted from the light emitter, and
a detecting portion comprising a program configured to, when executed by a processor, detect a position of the detected portion based on a light receiving state of the light receiver, the detected portion being inserted between the light emitter and the light receiver;
detecting a position of a linearly-extending edge portion of the detected portion by the line sensor while linearly moving the wrist portion based on a command value from the robot control portion such that the wrist portion intersects with the band-shaped light ray; and
diagnosing a property of a waving movement of the wrist portion in a linearly moving state based on the detected position of the linearly-extending edge portion.

2-6. (canceled)

7. The robot diagnosing method according to claim 1, wherein the light emitter emits the band-shaped light ray in an upward/downward direction.

8. The robot diagnosing method according to claim 1, wherein:
the robot is a semiconductor manufacturing robot configured to perform an operation in a clean room that is a semiconductor manufacturing site; and
the robot and the line sensor are prepared in the clean room.

9. The robot diagnosing method according to claim 8, wherein the line sensor is included in a prealigner.

10. (canceled)
